(19) United States
(12) Patent Application Publication
(10) Pub. No.: US 2015/0213884 A1
(43) Pub. Date: Jul. 30, 2015

(54) PARTITIONED RESISTIVE MEMORY ARRAY

(71) Applicants: Tarek M. Taha, Centerville, OH (US); Chris Yakopcic, Rocky River, OH (US)

(72) Inventors: Tarek M. Taha, Centerville, OH (US); Chris Yakopcic, Rocky River, OH (US)

(73) Assignee: UNIVERSITY OF DAYTON, Dayton, OH (US)

(21) Appl. No.: 14/168,416

(22) Filed: Jan. 30, 2014

(51) Int. Cl. G11C 13/00

(52) U.S. Cl. CPC G11C 13/004; G11C 13/0069

(57) ABSTRACT

A resistive memory array partitioned into a plurality of memory units is disclosed. Each memory unit includes a plurality of resistive memory elements, a plurality of row lines, a plurality of column lines, a plurality of row select switching devices, and a plurality of column select switching devices. Each resistive memory element is in communication with one of the row lines and one of the column lines. Each row line is in communication with a corresponding one of the row select switching devices. Each column line is in communication with a corresponding one of the column select switching devices.

### FIELD OF INVENTION

The present invention relates to a resistive memory array partitioned into a plurality of memory units, and methods for writing to and reading from the resistive memory array.

### BACKGROUND OF INVENTION

A multi-core processor, which is also referred to as a chip, may include two or more independent central processing units or cores that each read and execute program instructions. A first level of cache memory (an L1 cache) and a second level of cache memory (an L2 cache) may be associated with each core. Some chips may also include additional levels of cache memory as well. For example, the chip may include a third level of cache memory (an L3 cache) that is shared between the various cores. However, there is a limited amount of area available on the chip to accommodate all of the processing cores and the various levels of cache memory. Moreover, as technology advances, the number of cores included on the chip increase as well. Each core may require its own multi-level cache memory. Thus, it is becoming progressively difficult to fit all of the cores and the various levels of cache memory on a single chip.

Static random-access memory (SRAM) is traditionally used in cache memory systems. However, in an effort to reduce the amount of area on the chip occupied by the cache memory, denser types of memory are being investigated to replace the current SRAM such as, for example, resistive random access memory (RRAM). RRAM typically includes a relatively high bit density and low leakage power, which makes this type of memory an attractive replacement for SRAM. The three main types of RRAM are memristors, phase change random access memory (PCRAM), and spin-torque transfer magnetic random access memory (SST-MRAM). Memristors possess a much higher bit density when compared to SRAM, PCRAM and SST-RAM. Accordingly, memristor crossbar arrays have become an especially appealing candidate for use in memory applications. A memristor crossbar structure typically includes a set of upper wires that intersect a set of lower wires, where a memristive element is located at the intersections between the upper wires and the lower wires.

Although memristor crossbar arrays possess a relatively high bit density, several issues currently exist that make memristors challenging to use in memory applications. For example, high density memristor crossbar arrays, which do not include access transistors, tend to consume relatively large amounts of energy. Moreover, high density memristor crossbars arrays tend to also produce a significant number of read errors. This is because high density memristor crossbar arrays do not include access transistors that prevent current from flowing from one memristive element to another memristive element located within the array. Thus, an access transistor may be placed alongside each memristive element located in the memristor crossbar array to substantially reduce the number of read errors and energy consumption. This architecture may be referred to as a 1 transistor-1 memristor (1T1R) memory system. However, the areal density of the 1T1R memory system is limited by the size of the access transistor.

### SUMMARY OF INVENTION

In one embodiment, a resistive memory array partitioned into a plurality of memory units is disclosed. Each memory unit includes a plurality of resistive memory elements, a plurality of row lines, a plurality of column lines, a plurality of row select switching devices, and a plurality of column select switching devices. Each resistive memory element is in communication with one of the row lines and one of the column lines. Each row line is in communication with a corresponding one of the row select switching devices. Each column line is in communication with a corresponding one of the column select switching devices.

In another embodiment, method of operating a resistive memory array partitioned into a plurality of memory units is disclosed. The method includes providing the resistive memory array. Each memory unit includes a plurality of resistive memory elements, a plurality of row select switching devices, a plurality of column select switching devices, a plurality of row lines, and a plurality of column lines. Each of the resistive memory elements are in communication with one of the row lines and one of the column lines. The method includes generating a specific memory unit row select signal. The memory units are arranged in respective memory unit rows and respective memory columns within the resistive memory array. The method includes activating all of the row select switching devices located within a specific one of the memory unit rows based on the specific memory unit row select signal. Each row line is in communication with a corresponding one of the row select switching devices. The method includes activating all of the column select switching devices located within the specific one of the memory unit rows based on the specific memory unit row select signal. Each column line is in communication with a corresponding one of the column select switching devices.

### BRIEF DESCRIPTION OF THE DRAWINGS

FIG. 1 is a schematic block diagram illustrating a resistive memory device that includes a resistive memory array, a row decoder, a row pulse generator, a column circuit, and a control logic circuit;

FIG. 2 is schematic diagram illustrating a portion of the resistive memory array shown in FIG. 1, where the resistive memory array is partitioned into a plurality of tiles or memory units;

FIG. 2A is an enlarged view of a selected row of memory units shown in FIG. 2;

FIG. 2B is a main column circuit shown in FIG. 2A;

FIG. 3 is an enlarged view of one of the memory units shown in FIG. 2; and

FIG. 4 is a process flow diagram illustrating an exemplary method for writing to and reading from the resistive memory array.

### DETAILED DESCRIPTION

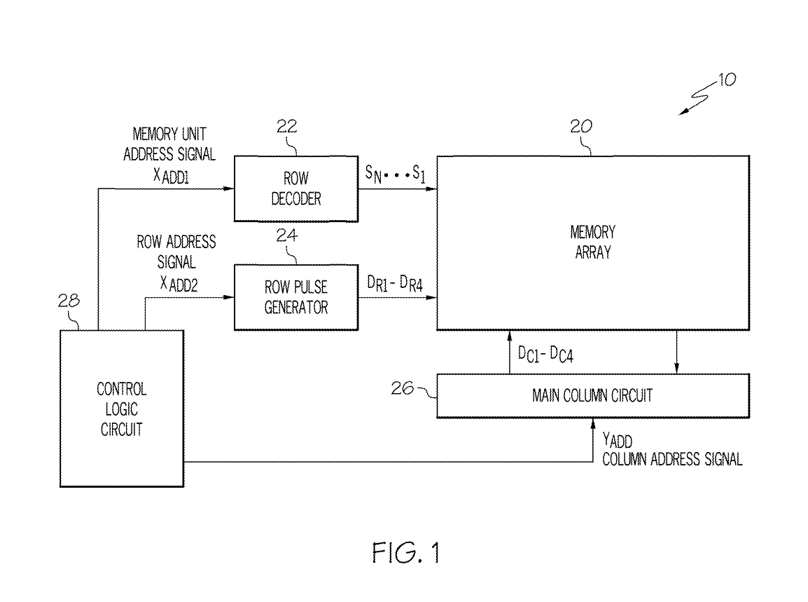

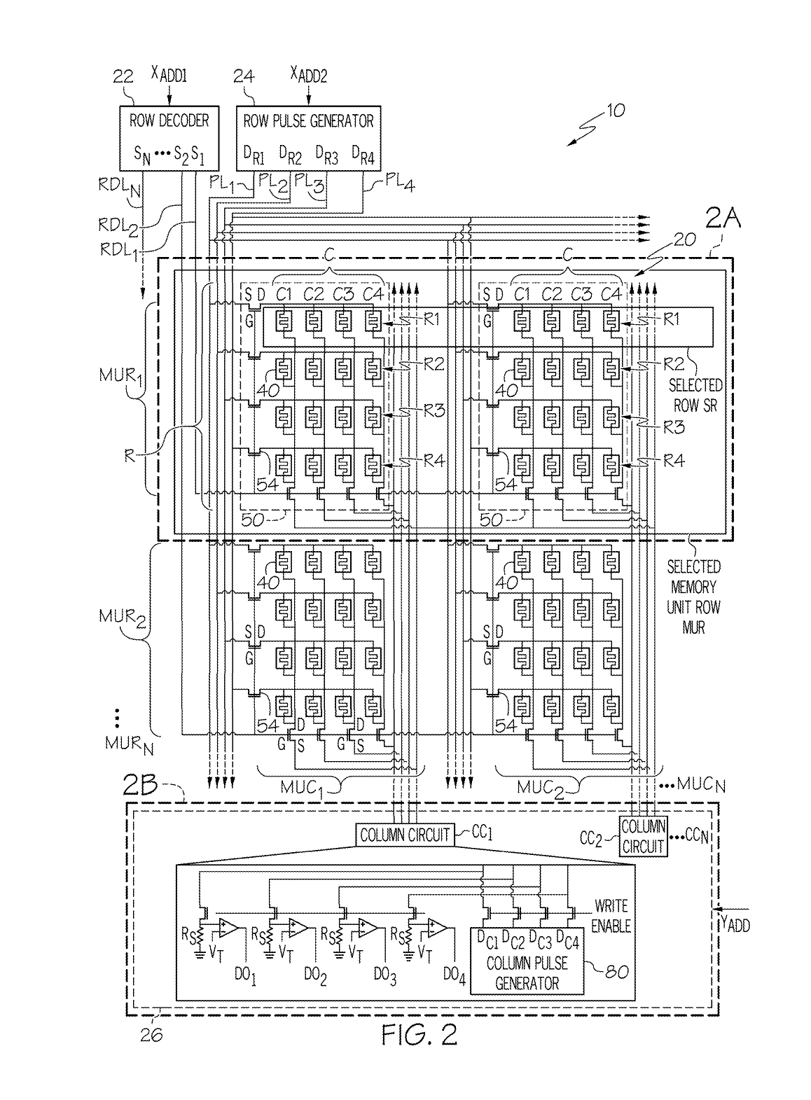

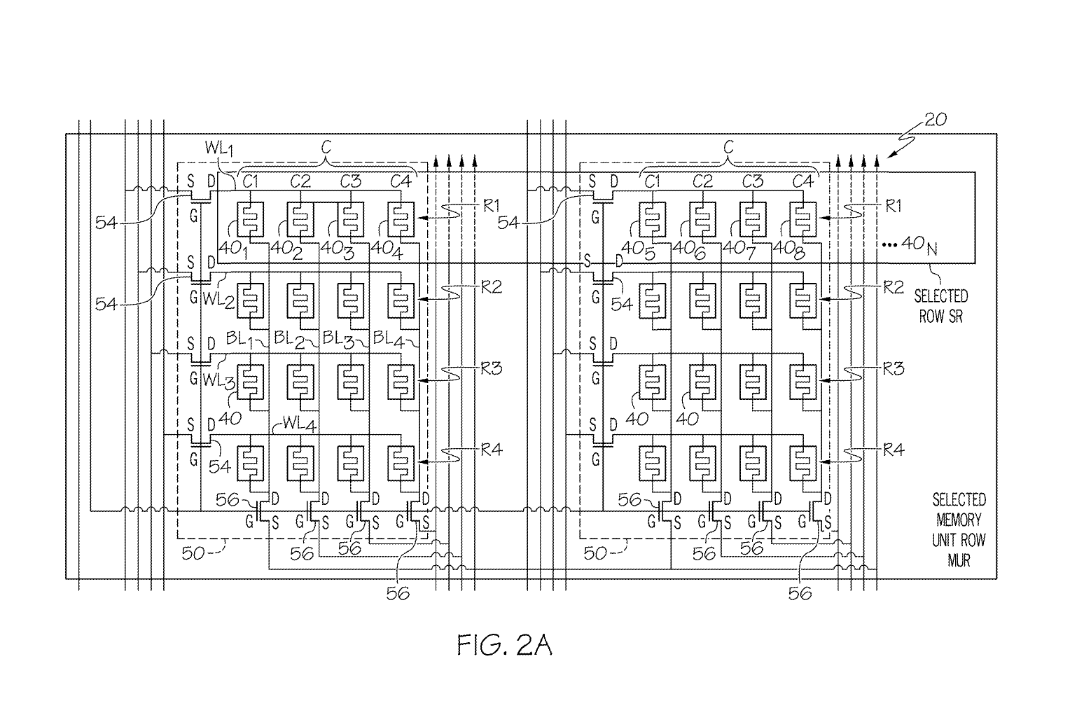

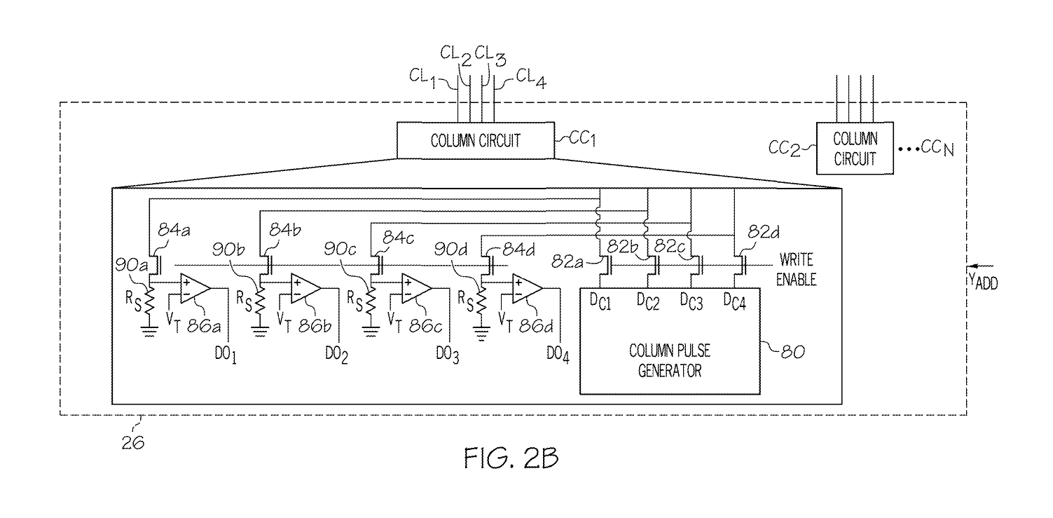

FIG. 1 illustrates a block diagram of a resistive memory device 10 according to one embodiment of the disclosure. In one non-limiting embodiment, the resistive memory device 10 may include a resistive memory array 20, a row decoder 22, a row pulse generator 24, a main column circuit 26, and a control logic circuit 28. The row decoder 22, the row pulse generator 24, the main column circuit 26, and the control logic circuit 28 may be used to control read and write operations on the resistive memory array 20. The resistive memory array 20 may include a plurality of resistive memory elements 40 (shown in FIG. 2). In one non-limiting embodiment, each resistive memory element 40 may be in either a high resistance state (which represents a “0”) or a low resistance state (which represents a “1”). However, those skilled in the art will appreciate that the resistive memory elements may include more than two states as well.

Referring to FIG. 2, the resistive memory array 20 may be partitioned into a plurality of smaller memory arrays, which may be referred to as tiles or memory units 50. Each tile or memory unit 50 may include a portion of the total number of resistive memory elements 40 located within the resistive memory array 20. The resistive memory elements 40 may be arranged in a plurality of rows R as well as a plurality of columns C within each memory unit 50. For example, in the non-limiting embodiment as shown in FIG. 2 the resistive memory elements 40 may be arranged in four rows R (R1-R4) and four columns C (C1-C4) within each memory unit 50.

The memory units 50 may also be arranged into memory unit rows MUR₁-MUR_{N} and memory unit columns MUC₁-MUC_{N} within the resistive memory array 20. The resistive memory array 20 may include N rows of memory units 50 as well as N columns of memory units, where N may be any number greater than one. FIG. 2 only illustrates a first memory unit row MUR₁ and a second memory unit row MUR₂, as well as a first memory unit column MUC₁ and a second memory unit column MUC₂ of memory units 50 for convenience and clarity. Moreover, while the resistive memory elements 40 and the memory units 50 are described as being arranged in rows R and columns C, this is to provide a coordinate system and for ease of explanation. Those skilled in the art will appreciate that this terminology does not necessarily refer to an actual physical orientation of the resistive memory elements 40 or the memory units 50 within the resistive memory array 20.

In the exemplary embodiment as illustrated in FIGS. 2 and 2A, a selected memory unit row MUR is shown. The selected memory unit row MUR includes each memory unit 50 located in the first memory unit row MUR₁ of the resistive memory array 20. For example, in the embodiment as described in FIGS. 2 and 2A, the selected memory unit row MUR would include N number of memory units 50. A selected row SR of resistive memory elements 40₁-40_{X} may be located within the selected memory unit row MUR, where X represents the total number of resistive memory elements 40 located in the selected row SR. Only eight of the resistive memory elements 40₁-40₈ within the selected row SR are shown in FIGS. 2 and 2A for purposes of convenience and clarity. The selected row SR includes each resistive memory element 40 located in a single row R of each memory unit 50 that is part of the selected memory unit row MUR. For example, in the embodiment as illustrated, the number X would be N×4, where the number N is the total number of memory units 50 located in the selected memory unit row MUR, and 4 is the number of memory elements 40 located in row R1 of each memory unit 50.

Data may be read from or written to each resistive memory element 40₁-40_{X} located within the selected row SR of the resistive memory array 20. However, while read and write operations being performed on the selected resistive memory elements 40₁-40_{X} are described and shown in FIG. 2, it is to be understood that this illustration is exemplary in nature. Those skilled in the art will appreciate that read and write operations may be performed on the resistive memory elements 40 located within any single row R of each memory unit 50 within the selected memory unit row MUR. Moreover, although FIGS. 2 and 2A show the selected memory unit row MUR as the first memory unit row MUR₁, it is to be understood that this illustration is merely exemplary in nature. Any one of the remaining memory unit rows MUR₂-MUR_{N} may be the selected memory unit row MUR instead.

Referring to FIGS. 1,-2, and 2A, the resistive memory array 20 may be in communication with the row decoder 22, the row pulse generator 24, and the column circuit 26. The control logic circuit 28 may control read and write operations executed by the row decoder 22, the row pulse generator 24, and the column circuit 26. Specifically, the control logic circuit 28 may send a memory unit address signal X_{ADD1} to the row decoder 22. The memory unit address signal X_{ADD1} indicates addresses of the selected memory unit row MUR. For example, in the embodiment as shown, the memory unit address signal X_{ADD1} would indicate the addresses of the first row MUR₁ of memory units 50. The control logic circuit 28 may also send a row address signal X_{ADD2} to the row pulse generator 24. The row address signal X_{ADD2} indicates addresses of each row R in every memory unit 50 in the resistive memory array 20 where the selected row SR may potentially be located within the resistive memory array 20. For example, in the embodiment as illustrated where the selected row SR is shown, the memory unit address signal X_{ADD2} would indicate the addresses of row R1 of each memory unit 50 in the resistive memory array 20.

The control logic circuit 28 may also send a column address signal Y_{ADD} to the main column circuit 26. In the event a read operation is being executed, the column address signal Y_{ADD} directs current towards a plurality of sense resistors 90a-90b located within the main column circuit 26, which is discussed in greater detail below. In the event a write operation is being executed, the column address signal Y_{ADD} indicates which resistive memory elements 40₁-40_{X} located within the selected row SR are written to, which is also discussed in greater detail below.

Referring to FIGS. 2 and 2A, each row R of each memory unit 50 may include a row select switching device 54. Similarly, each column C of each memory unit 50 may include a column select switching device 56. The row select switching devices 54 and the column select switching devices 56 may be any type of active electronic switching device capable of directing current flow. For example, in one embodiment, the row select switching devices 54 and the column select switching devices 56 may be transistors. Specifically, in the exemplary embodiment as shown in FIG. 2, the switching row select switching devices 54 and the column select switching devices 56 are metal-oxide-semiconductor field-effect transistors (MOSFETS) that each include a gate G, a source S, and a drain D.

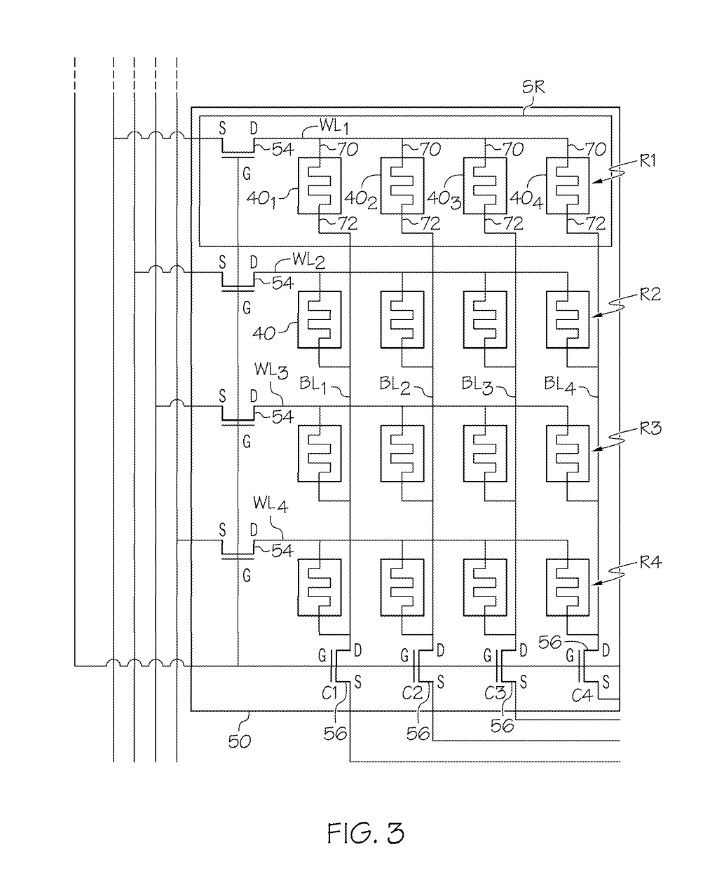

Referring to FIG. 3, each resistive memory element 40 may include a first portion 70 and a second portion 72. The first portion 70 of each resistive memory element 40 may be coupled to a corresponding word line WL, and the second portion 72 of the resistive memory element 40 may be coupled to a corresponding bit line BL. The words lines WL and the bit lines BL allow for information to travel to and from the resistive memory elements 40. The word lines WL may also be referred to as row lines, and the bit lines BL may also be referred to as column lines.

All of the resistive memory elements 40 and the row select switching device 54 associated with a single one of the rows R within a single memory unit 50 may each be coupled to the same word line WL. For example, each first portion 70 of the selected resistive memory elements 40₁-40₄ located within row R1 may each be coupled to the word line WL₁. The drain D of the row select switching device 54 located in row R1 may also be coupled to the word line WL₁. Similarly, all of the resistive memory elements 40 and the column select switching device 56 associated with a single one of the columns C within a memory unit 50 may each be coupled to the same bit line BL. For example, each second portion 72 of the resistive memory elements 40 located within column C1 may each be coupled to the bit line BL₁. The drain D of the column select switching device 56 located in column C1 may also be coupled to the common bit line BL₁.

The row select switching devices 54 may each selectively allow current to flow through a corresponding word line WL, and to the resistive memory elements 40 in communication with the corresponding word line WL. For example, when the row select switching device 54 located in row R1 is activated, current may flow through the word line WL₁ and to the resistive memory elements 40₁-40₄. Similarly, the column select switching devices 56 may each selectively allow current to flow through a corresponding bit line BL, and to the resistive memory elements 40 in communication with the corresponding bit line BL. For example, when the column select switching device 56 located in column C1 is activated, current may flow through the bit line BL₁ and to the resistive memory elements 40 coupled to the bit line BL₁.

Referring to FIGS. 2 and 2A, the row select switching devices 54 and the column select switching devices 56 may also be used to isolate the resistive memory elements 40 located within each memory unit 50. Specifically, the row select switching devices 54 and the column select switching devices 56 may restrict the flow of current through the word lines WL and the bit lines BL to a specific memory unit 50. Thus, current flowing through one or more of the resistive memory elements 40 in one of the memory units 50 may not flow to one of the resistive memory elements 40 located another memory unit 50 located within the resistive memory array 20. Isolating the memory elements 40 located within each of the memory units 50 may reduce the occurrence of read errors within the resistive memory array 20.

The resistive memory elements 40 may be used to store analog information. When a specific amount of current has passed through the resistive memory element 40 in a particular direction, the resistive memory element 40 ceases to further integrate current in the particular direction. Thus, the resistive memory elements 40 may include a maximum or off-state resistance R_{OFF} and a minimum or on-state resistance R_{ON}. In one embodiment, the resistive memory array 20 may be composed of any type of resistive memory elements 40 that have an on-state resistance R_{ON} of at least about 10 ohms. However, if the row select switching device 54 and the column select switching device 56 are transistors, then the resistive memory elements 40 may require a higher on-state resistance R_{ON} of about 100 ohms. In one non-limiting embodiment, the resistive memory elements 40 may be memristors.

In the exemplary embodiment as shown in FIGS. 2, 2A, and 3, the memory units 50 each include a 4×4 array of resistive memory elements 40, resulting in four rows R1-R4 and four columns C1-C4 with a total of sixteen resistive memory elements 40 per memory unit 50. However, it is to be understood the memory units 50 may include any number of resistive memory elements 40. For example, in one embodiment the memory units 50 may each include a 8×8 array of resistive memory elements 40, resulting in a total of eight rows and eight columns with a total of sixty-four resistive memory elements 40 per memory unit 50. FIGS. 2, 2A, and 3 illustrate the memory units 50 having an equal number of resistive memory elements 40 located in each of the rows R and each of the columns C. However, it is to be understood that in another embodiment the memory units 50 may include a first number A of resistive memory elements 40 located in each of the rows R, and a second number B of resistive memory elements located in each of the columns C, where the number A is not equal to the number B. For example, in one embodiment, the memory units 50 may each include a 8×4 array of resistive elements 40.

Although the memory units 50 may include any number of resistive memory elements 40, it is to be understood that larger memory units 50 having an increased number of resistive memory elements 40 may be beneficial. This is because an increased number of resistive memory elements 40 per memory unit 50 results in a higher bit density of the resistive memory array 20. A higher bit density allows for a greater volume of data to be stored in the resistive memory array 20 using the same amount of physical space.

The number of resistive memory elements 40 included within each memory unit 50 may be based on an off-state versus on-state resistance ratio R_{OFF}/R_{ON}. Specifically, as the off-state versus on-state resistance ratio R_{OFF}/R_{ON} increases, the number of read errors within each memory unit 50 decreases. This is because a relatively high off-state versus on-state resistance ratio R_{OFF}/R_{ON} may reduce the chance that one of the resistive memory elements 40 that is actually in an off-state may be mistaken to be in an on-state. For example, in one non-limiting embodiment, a 4×4 or an 8×8 array of resistive memory elements 40 may include an off-state versus on-state resistance ratio R_{OFF}/R_{ON} of 10⁶ and an on-state resistance R_{ON} of 125 kΩ.

Referring generally to FIGS. 2 and 2A-2B, operation of the row decoder 22, the row pulse generator 24, the column circuit 26 may now be discussed. While a resistive memory array having 4×4 memory units 50 is described and shown in the figures, it is to be understood that this illustration is exemplary in nature. Those skilled in the art will appreciate that the circuitry of the row decoder 22, row pulse generator 24, and the column circuit 26 may be adjusted to accommodate memory units 50 of any size (e.g., a 8×8 array or a 8×4 array). Those skilled in the art will also appreciate that circuitry associated with the row decoder 22, row pulse generator 24, and the column circuit 26 as shown in the figures illustrate only one non-limiting embodiment of the resistive memory device 10, and that other configurations of circuitry may be used as well, and may also accommodate memory units 50 of any size possible (e.g., a 8×8 array or a 8×4 array).

In the exemplary embodiment as shown, the row decoder 22 may be in communication with an N number of row decoder lines RDL₁-RDL_{N}, where each row decoder line RDL₁-RDL_{N} corresponds to one of the memory unit rows MUR₁-MUR_{N} within the resistive memory array 20. The gate G of each row select switching device 54 and each column select switching device 56 may be in communication with a corresponding one of the row decoder lines RDL₁-RDL_{N}. For example, row decoder line RDL₁ is in communication with the gate G of each row select switching device 54 and each column select switching device 56 located within the first memory unit row MUR₁. Likewise, row decoder line RDL₂ is in communication with the gate G of each row select switching device 54 and each column select switching device 56 located within the second memory unit row MUR₂.

Referring to FIGS. 1, 2, and 2A the row decoder 22 may receive the memory unit address signal X_{ADD1} from the control logic circuit 28. The row decoder 22 may generate a single, specific memory unit row select signal S based on the memory unit address signal X_{ADD1}. The specific memory unit row select signal S may be transmitted through one of the row decoder lines RDL₁-RDL_{N}. For example, row decoder line RDL₁ may transmit memory unit row select signal S₁, row decoder line RDL₂ may transmit memory unit row select signal S₂, and row decoder line RDL_{N} may transmit memory unit row select signal S_{N}. The specific memory unit row select signal S may activate all of the row select switching devices 54 and the column select switching devices 56 located in a corresponding one of the memory unit rows MUR₁-MUR_{N}. For example, in the embodiment as shown the row decoder 22 may receive the memory unit address signal X_{ADD1} from the control logic circuit 28 indicating addresses of the first memory unit row MUR₁. The row decoder 22 may then transmit the row select signal S₁ through the row decoder line RDL₁, which activates all of the row select switching devices 54 and the column select switching devices 56 located within the first memory unit row MUR₁.

In the exemplary embodiment as shown, the row pulse generator 24 may be in communication with four pulse generator lines PL₁-PL₄. Each pulse generator line PL₁-PL₄ corresponds to one of the rows R1-R4 within each memory unit 50. Each pulse generator line PL₁-PL₄ may be in communication with the source S of the row select switching device 54 located within the corresponding row R. For example, pulse generator line PL₁ is in communication with the source S of the row select switching devices 54 located in row R1 of each memory unit 50.

Referring to FIGS. 1, 2, and 2A, the row pulse generator 24 may receive the row address signal X_{ADD2} from the control logic circuit 28. The row pulse generator 24 may generate a single row select signal D_{R} based on the memory unit address signal X_{ADD2}. The row select signal D_{R} may be transmitted through one of the pulse generator line PL₁-PL₄. For example, pulse generator line PL₁ may transmit row select signal D_{R1}, pulse generator line PL₂ may transmit row select signal D_{R2}, and pulse generator line PL₃ may transmit row select signal D_{R3}, and pulse generator line PL₄ may transmit row select signal D_{R4}. The row pulse generator 24 may send one of the row select signals D_{R1}-D_{R4} to a corresponding one of the rows R1-R4 of resistive memory elements 40 located in each memory unit 50. For example, the row select signal D_{R1} may be sent to the first row R1 of resistive memory elements 40 located in each of the memory units 50 in the resistive memory array 20. However, the signal D_{R1} only impacts the resistive memory devices 40 located within the located in the first memory unit row MUR₁. This is because only the row select switching devices 54 and the column select switching devices 56 located within the first memory unit row MUR₁ have been activated.

The row select signal D_{R} may be either a read signal or a write signal. If a read operation is being executed, then the row select signal D_{R} may include a read voltage that is below a threshold voltage V_{Th} of the resistive memory elements 40. The threshold voltage V_{Th} represents the voltage required to change a resistive state of the resistive memory elements 40.

If a write operation is being executed, then the row select signal D_{R} may include a predetermined voltage. In one exemplary embodiment, the predetermined voltage is about half a write voltage V_{w} of the resistive memory elements 40. The write voltage V_{w} should be greater than a threshold voltage V_{Th} of the resistive memory elements 40. However, the predetermined voltage should be less than the threshold voltage V_{Th}. The row select signal D_{R} may include either positive or negative voltage value. For example, if a low resistance state (e.g., a “1”) is to be written to one or more of the resistive memory elements 40₁-40_{X}, then the row select signal D_{R} is a positive value with respect to the remaining rows of resistive memory elements 40. If a high resistance state (e.g., a “0”) is to be written to one or more of the resistive memory elements 40₁-40_{X}, then the row select signal D_{R} is a negative value with respect to the remaining rows of resistive memory elements 40. Although the row select signal D_{R} is described as either positive or negative voltage value, those skilled in the art will appreciate that other approaches for writing to the resistive memory elements 40 may be used as well. For example, in another embodiment applying the write voltage V_{w} would write a low resistance state to the memory elements 40, applying zero volts would write a high resistance state to the memory elements 40, and applying half the write voltage V_{w} would produce no change in an unselected memory element 40.

Referring to FIGS. 2 and 2A-2B, in one non-limiting embodiment the main column circuit 26 may include a plurality of individual column circuits CC₁-CC_{N}. Each column circuit CC₁-CC_{N} corresponds to one of the memory unit columns MUC₁-MUC_{N}. For example, the first column circuit CC₁ corresponds to the first memory unit column MUC₁, and the second column circuit CC₂ corresponds to the second memory unit column MUC₁. It is to be understood that the second column circuit CC₂ is not fully illustrated in FIG. 2 for purposes of convenience and clarity. In one non-limiting embodiment, each column circuit CC₁-CC_{N} may include a column pulse generator 80, a plurality of write enable transistors 82a-82d, a plurality of read enable transistors 84a-84d, a plurality of comparators 86a-86d, and a plurality of sense resistors 90a-90d, and a plurality of column lines CL₁-CL₄. Moreover, although the column circuits CC₁-CC_{N} are discussed as corresponding to one of the memory unit columns MUC₁-MUC_{N}, it is to be understood that in an alternative embodiment a single column circuit may be utilized as well, where the single column circuit does not read multiple the memory unit columns MUC₁-MUC_{N} together in parallel.

Each write enable transistor 82, read enable transistor 84, comparator 86, sense resistor 90, and column line CL corresponds to one of the columns C of resistive memory elements 40 in each memory unit 50 located in a corresponding one of the memory unit columns MUC₁-MUC_{N}. For example, the write enable transistor 82a, read enable transistor 84a, comparator 86a, sense resistor 90a, and column line CL₁ each correspond to the first column C1 of resistive memory elements 40 located in the first memory unit column MUC₁. Moreover, each column line CL₁-CL₄ may be in communication with the source S of the column select switching device 56 located within a corresponding one of the columns C₁-C₄ in each memory unit 50 located in a corresponding one of the memory unit columns MUC₁-MUC_{N}. For example, column line CL₁ may be in communication with the source S of the column select switching devices 56 located in each column C₁ in each memory unit 50 located in the first memory unit columns MUC₁.

Referring to FIGS. 1, 2, and 2A-2B, the main column circuit 26 receives the column address signal Y_{ADD} from the control logic circuit 28. The column circuits CC₁-CC₂ may perform a read or write operation. For example, if a write operation is executed, the write enable transistors 82a-82d may be activated, and the read enable transistors 84a-84d may be deactivated. The column pulse generator 80 may then send a write signal D_{C} through a corresponding one of the column lines CL₁-CL₄. For example, write signal D_{C1} may be sent though column line CL₁ to the resistive memory elements 40 located in the first column C1, write signal D_{C2} may be sent though column line CL₂ to the resistive memory elements 40 located in the second column C2, write signal D_{C3} may be sent though column line CL₃ to the resistive memory elements 40 located in the third column C3, and write signal D_{C4} may be sent though column line CL₄ to the resistive memory elements 40 located in the fourth column C4. Likewise, the column circuit CC₂ may also send a write signal D_{C} through a corresponding one of the column lines CL₁-CL₄. Moreover, the column circuits CC₃-CC_{N} (not shown) may each send a write signal D_{C} through a corresponding one of the column lines CL₁-CL₄.

The column address signal Y_{ADD} from the control logic circuit 28 indicates which specific resistive memory elements 40₁-40_{X} located within the selected row SR should be written to. The write signal D_{C} may then apply the predetermined voltage to the specific resistive memory elements 40₁-40_{X}. For example, in one embodiment the predetermined voltage applied by the write signal D_{C} may be a negative value to change one of the resistive memory elements 40₁-40_{X} to a low resistance state (e.g., a “1”). Furthermore, the predetermined voltage may be a positive value to change one of the resistive memory elements 40₁-40_{X} to a high resistance state (e.g., a “0”).

In one illustrative example, if the column address signal Y_{ADD} from the control logic circuit 28 indicates that the memory elements 40₂, 40₄, and 40₈ should be written to, then the pulse generator 80 located within the first column circuit CC₁ generates write signals D_{C2} and write signal D_{C4}. Similarly, the pulse generator located within the second column circuit CC₂ (not shown) generates write signal D_{C4}. The write signal D_{C2} from the first column circuit CC₁ is applied to all of the resistive memory elements 40 located within the second column C2 of each memory array 50 located within the first memory unit column MUC₁. Similarly, the write signal D_{C4} from the first column circuit CC₁ is applied to all of the resistive memory elements 40 located within the fourth column C4 of each memory array 50 located within the first memory unit column MUC₁. Moreover, the write signal D_{C4} from the second column circuit CC₂ is applied to all of the resistive memory elements 40 located within the fourth column C4 of each memory array 50 located within the second memory unit column MUC₂.

Although the write signals D_{C2} and D_{C4} from the first column circuit CC₁ may be sent to all of the memory elements 40 located within the second column C2 and the fourth column C4 of each memory array 50 located within the first memory unit column MUC₁, the write signal D_{C2} may only write to the selected resistive memory elements 40₂ located within the selected row SR of the selected memory unit row MUR. Similarly, the write signal D_{C4} may only write to the selected resistive memory elements 40₄ located within the selected row SR of the selected memory unit row MUR. Moreover, while the write signal D_{C4} from the second column circuit CC₂ may be sent to all of the memory elements 40 located within the fourth column C4 of each memory array 50 located within the second memory unit column MUC₂, the write signal D_{C4} may only write to the selected resistive memory element 40₈ located within the selected row SR of the selected memory unit row MUR. This is because the memory unit row select signal S₁ that was sent by the row decoder 22 only activated the row select switching devices 54 and the column select switching devices 56 located within the first memory unit row MUR₁. Also, the write signal D_{R1} that was sent by the row pulse generator 24 only applied the predetermined voltage to the resistive memory elements 40 located within the first row R1 of every memory unit 50 located In the resistive memory array 20.

If a read operation is executed, then the write enable transistors 82a-82d may be deactivated. The column address signal Y_{ADD} from the control logic circuit 28 activates the read enable transistors 84a-84d located in each of the column circuits CC₁-CC_{N}. A sense voltage may then be measured across each of the sense resistors 90a-90d located in each of the column circuits CC₁-CC_{N}. The sense voltage generally represents a voltage division between the resistance of the corresponding resistive memory element 40 and the specific sense resistor 90. For example, the sense voltage across the sense resistor 90a generally represents the voltage division between a resistance of the resistive memory element 40₁ (located within the first row R1) and the resistance of the specific sense resistor 90a.

The comparators 86a-86d located in each of the column circuits CC₁-CC_{N} may then convert the analog value of the sense voltage across a corresponding one of the sense resistors 90a-90d into a digital value. Specifically, each comparator 86a-86d may compare the sense voltage across a corresponding one of the sense resistor 90a-90d with a reference voltage V_{T}. The comparators 86a-86d may then determine a digital output DO based on the comparison. For example, in one embodiment, if the sense voltage across each the resistor 90a is greater than the reference voltage V_{T}, then the comparator 86a generates a high digital output DO₁ (e.g., 1). Similarly, if the sense voltage across the resistor 90a is less than the reference voltage V_{T}, then the comparator 86a generates a low digital output DO₁ (e.g., 0). It should be noted that while comparators 86a-86d are illustrated in FIG. 2, it is to be understood that other approaches may be used as well to convert the analog value of the sense voltage across the sense resistors 90a-90d into a digital value.

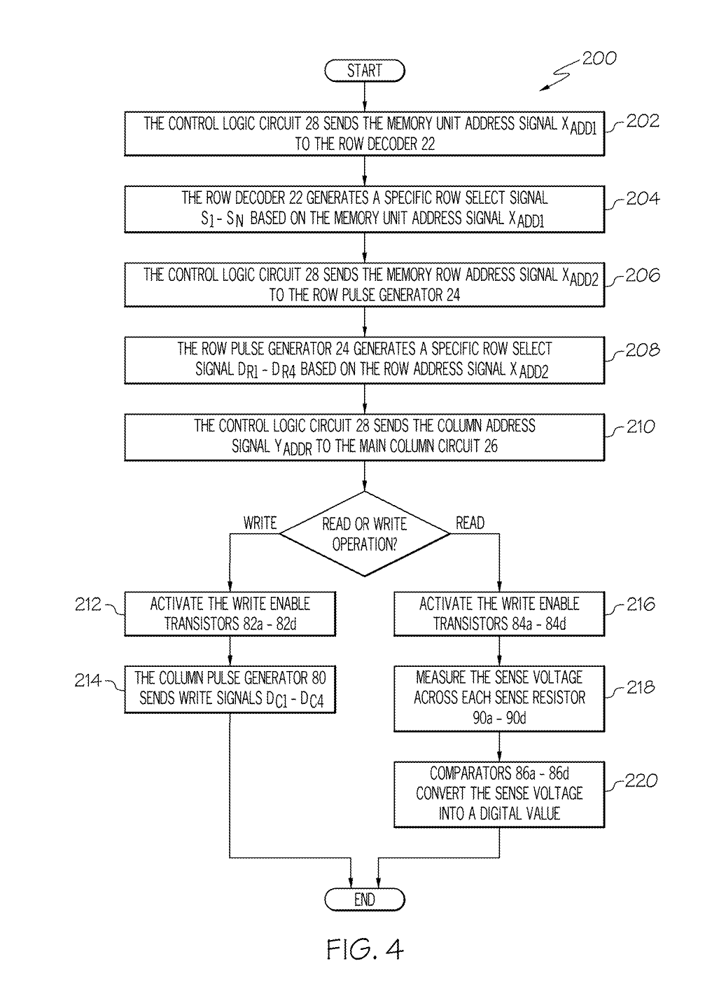

A method of operating the resistive memory array 20 will now be described. FIG. 4 is a process flow diagram illustrating an exemplary method 200 of either writing to or reading from the resistive memory array 20. Referring generally to FIGS. 1-4, method 200 may begin at block 202, where the control logic circuit 28 may send the memory unit address signal X_{ADD1} to the row decoder 22. The memory unit address signal X_{ADD1} indicates addresses of a selected memory unit row MUR. For example, in the embodiment as shown in FIG. 2 the memory unit address signal X_{ADD1} would indicate the addresses of the first row MUR₁ of memory units 50. Method 200 may then proceed to block 204.

In block 204, the row decoder 22 may generate a specific memory unit row select signal S based on the memory unit address signal X_{ADD1}. The specific memory unit row select signal S may activate all of the row select switching devices 54 and the column select switching devices 56 located in the selected memory unit row MUR. For example, in the embodiment as shown in FIG. 2 the row decoder 22 may transmit the row select signal S₁ through the row decoder line RDL₁, which activates all of the row select switching devices 54 and the column select switching devices 56 located within the first row MUR₁. Method 200 may then proceed to block 206.

In block 206, the control logic circuit 28 may send the row address signal X_{ADD2} to the row pulse generator 24. The row address signal X_{ADD2} indicates addresses of each row R in every memory unit 50 where the selected row SR may potentially be located in the resistive memory array 20. For example, in the embodiment of FIG. 2 where the selected row SR is shown, the memory unit address signal X_{ADD2} would indicate the addresses of row R1 of each memory unit 50 in the resistive memory array 20. Method 200 may then proceed to block 208.

In block 208, the row pulse generator 24 may generate a single row select signal D_{R}. The row select signal D_{R} may be sent to one of the rows R1-R4 of resistive memory elements 40 located in each memory unit 50 of the memory array 20. For example, the row select signal D_{R1} may be sent to the first row R1 of resistive memory elements 40 in each of the memory units 50 in the memory array 20. It is to be understood that the row select signal D_{R} may be a read signal or a write signal. For example, if a write operation is selected, then the row select signal D_{R} may include the predetermined voltage. If a read operation is selected, then the row select signal D_{R} may include the read voltage. Method 200 may then proceed to block 210.

In block 210, the control logic circuit 28 may send the column address signal Y_{ADD} to the main column circuit 26. In the event a write operation is being executed, method 200 may then proceed to block 212. However, if a read operation is being executed, method 200 may then proceed to block 216.

In block 212 where a write operation is executed, the write enable transistors 82a-82d may be activated, and the read enable transistors 84a-84d may be deactivated. Method 200 may then proceed to block 214.

In block 214, the column pulse generator 80 located within each column circuit CC₁-CC_{N} may send multiple at least one write signal D_{C} through a corresponding one of the column lines CL₁-CL₄. The write signal D_{C} may then apply the predetermined voltage to the specific resistive memory elements 40₁-40_{X} that should be written to. Method 200 may then terminate, or return to block 202.

In block 216 where a read operation is being executed, the column address signal Y_{ADD} from the control logic circuit 28 activates the read enable transistors 84a-84d located in each of the column circuits CC₁-CC_{N}. Method 200 may then proceed to block 218.

In block 218, the sense voltage may be measured across each of the sense resistors 90a-90d in each of the column circuits CC₁-CC_{N}. Method 200 may then proceed to block 220.

In block 220, the comparators 86a-86d located in each of the column circuits CC₁-CC_{N} may convert the analog value of the sense voltage across a corresponding one of the sense resistors 90a-90d into a digital value. Specifically, each comparator 86a-86d may compare the sense voltage across a corresponding one of the sense resistor 90a-90d with the reference voltage V_{T} and determine the digital output DO based on the comparison. Method 200 may then terminate, or return to block 202.

Referring generally to FIGS. 1-4, the disclosed resistive memory array 20 may consume substantially less power when compared to some types of high density memristor crossbar arrays that are currently available. For example, one type of resistive memory array having an on-state resistance R_{ON} of 125 kOhms, an off-state resistance R_{OFF} of 125 GOhms, an off-state versus on-state resistance ratio R_{OFF}/R_{ON} of 10⁶, a threshold voltage V_{Th} of 4V, and a switching time of 10 ns may be referred to as Device X. Another type of resistive memory array having an on-state resistance R_{ON} of 500 kOhms, an off-state resistance R_{OFF} of 1 GOhms, an off-state versus on-state resistance ratio R_{OFF}/R_{ON} of 2000, a threshold voltage V_{Th} of 0.6V, and a switching time of 50 ns may be referred to as Device Y. Table 1 summarizes the read energies and write energies of Device X (based on 4×4 arrays and a 8×8 arrays of memory units), Device Y (based on 4×4 arrays of memory units), and a prior art high density crossbar array that does not include access transistors. The prior art high density crossbar array is based on the properties of Device X (i.e., the same on-state resistance R_{ON}, off-state resistance R_{OFF}, off-state versus on-state resistance ratio R_{OFF}/R_{ON}, threshold voltage V_{Th}, and switching time). It should be noted that the read and write energies listed in Table 1 for the prior art high density crossbar array have been extrapolated.

TABLE 1

| | Device X | Device X | Device Y | High Density |
|---|---|---|---|---|
| Memory | (4 × 4 | (8 × 8 | (4 × 4 | Crossbar Array |
| Architecture | array) | array) | array) | (Prior Art) |
| Read Energy (fJ/bit) | 4.593 | 6.180 | 0.0441 | 21 |
| Write Energy | 3265 | 6536 | 117 | 70000 |
| (fJ/bit) | | | | |

As shown in Table 1, both Device X and Device Y consume less than ten percent of the write energy of the high density crossbar array, and less than one-third of the read energy of the high density crossbar array. Moreover, the disclosed resistive memory array 20 may have a significantly higher bit density when compared to static random-access memory (SRAM) and spin-torque transfer magnetic random access memory (SST-MRAM). For example, Device X (based on 8×8 arrays of memory units) may have a bit density that is over eleven times denser than SRAM and over three times as dense as SST-RAM. A higher bit density allows for a greater volume of data to be stored in memory using the same amount of physical space.

The disclosed resistive memory array 20 may be used in a variety of different memory applications. For example, in one non-limiting embodiment the resistive memory array 20 may be part of a cache memory system located on a multi-core processor. In particular, the resistive memory array 20 may be used in lower levels of cache memory, such as level one caches (L1 caches) or level two caches (L2 caches). Some other types of memory applications that may utilize the resistive memory array 20 include, but are not limited to, solid-state drives (SSD), Universal Serial Bus (USB) memory drives, and memory cards.

Having described the invention in detail and by reference to preferred embodiments thereof, it will be apparent that modifications and variations are possible without departing from the scope of the invention as defined by the following claims.

What is claimed is:

1. A resistive memory device, comprising:
a resistive memory array partitioned into a plurality of memory units, wherein each memory unit includes:
a plurality of resistive memory elements;
a plurality of row lines, wherein each resistive memory element is in communication with one of the row lines;
a plurality of column lines, wherein each resistive memory element is in communication with one of the column lines;
a plurality of row select switching devices, wherein each row line is in communication with a corresponding one of the row select switching devices; and
a plurality of column select switching devices, wherein each column line is in communication with a corresponding one of the column select switching devices.

2. The resistive memory device of claim 1, wherein the memory units are arranged in respective memory unit rows and respective memory unit columns within the resistive memory array.

3. The resistive memory device of claim 2, further comprising a row decoder in communication with the resistive memory array, wherein the row decoder is configured to generate a specific memory unit row select signal that corresponds to a specific one of the respective memory unit rows.

4. The resistive memory device of claim 3, further comprising a row pulse generator in communication with the resistive memory array, wherein the row pulse generator is configured to generate a row select signal that corresponds to one of the row lines of each memory unit within the resistive memory array.

5. The resistive memory device of claim 4, wherein the row select signal is a read signal and includes a read voltage, and wherein the read voltage is below a threshold voltage of the resistive memory elements.

6. The resistive memory device of claim 4, wherein the row select signal is a write signal and includes a predetermined voltage, and wherein the predetermined voltage is about half a write voltage of the resistive memory elements.

7. The resistive memory device of claim 4, further comprising a main column circuit in communication with the resistive memory array, wherein the main column circuit includes a plurality of column circuits that each correspond to one of the respective memory unit columns in the resistive memory array.

8. The resistive memory device of claim 7, wherein each of the column circuits located in the main column circuit include a plurality of sense resistors, and wherein each of the sense resistors corresponds to one of the column lines in the memory units.

9. The resistive memory device of claim 7, wherein each of the column circuits located in the main column circuit include a column pulse generator configured to send write signals to at least one of the column lines in the memory units.

10. The resistive memory device of claim 1, wherein the resistive memory elements have an on-state resistance R_{ON} of at least about 10 ohms.

11. The resistive memory device of claim 1, wherein the row select switching devices and the column select switching devices are transistors.

12. The resistive memory device of claim 11, wherein the resistive memory elements have an on-state resistance R_{ON} of at least about 100 ohms.

13. The resistive memory device of claim 1, wherein the resistive memory elements are memristors.

14. The resistive memory device of claim 1, wherein the plurality of memory units each include an equal number of resistive memory elements located in each row line and each column line.

15. The resistive memory device of claim 1, wherein the plurality of memory units each include first number of resistive memory elements located in each row line and a second number of resistive memory elements located in each column line, and wherein the first number and the second number are not equal to one another.

16. A method of operating a resistive memory array partitioned into a plurality of memory units, the method comprising:
providing the resistive memory array, wherein each memory unit includes a plurality of resistive memory elements, a plurality of row select switching devices, a plurality of column select switching devices, a plurality of row lines, and a plurality of column lines, and wherein each of the resistive memory elements are in communication with one of the row lines and one of the column lines;
generating a specific memory unit row select signal, wherein the memory units are arranged in respective memory unit rows and respective memory columns within the resistive memory array;
activating all of the row select switching devices located within a specific one of the memory unit rows based on the specific memory unit row select signal, wherein each row line is in communication with a corresponding one of the row select switching devices; and
activating all of the column select switching devices located within the specific one of the memory unit rows based on the specific memory unit row select signal, wherein each column line is in communication with a corresponding one of the column select switching devices.

17. The method as recited in claim 16, further comprising providing a row decoder in communication with the resistive memory array, wherein the row decoder generates the specific memory unit row select signal.

18. The method as recited in claim 16, further comprising generating a row select signal by a row pulse generator in communication with the resistive memory array.

19. The method as recited in claim 18, wherein the row select signal is sent to one of the row lines of each memory unit within the resistive memory array.

20. The method as recited in claim 19, wherein the row select signal is a read signal and includes a read voltage, and wherein the read voltage is below a threshold voltage of the resistive memory elements.

21. The method as recited in claim 19, wherein the row select signal is a write signal and includes a predetermined voltage, and wherein the predetermined voltage is about half a write voltage of the resistive memory elements.

22. The method as recited in claim 18, further comprising providing a main column circuit in communication with the resistive memory array, wherein the main column circuit includes a plurality of column circuits that each correspond to one of the respective memory unit columns in the resistive memory array.

23. The method as recited in claim 22, wherein each of the column circuits located in the main column circuit include a plurality of sense resistors, wherein each sense resistor corresponds to one of the column lines in the memory units.

24. The method as recited in claim 23, comprising measuring a sense voltage across each of the plurality of sense resistors, wherein the sense voltage generally represents a voltage division between the resistance of a corresponding one of resistive memory elements and a specific sense resistor.

25. The method as recited in claim 24, comprising converting the sense voltage into a digital value.

26. The method as recited in claim 22, wherein each of the column circuits located in the main column circuit include a column pulse generator configured to send write signals to at least one of the column lines in the memory units.

27. The method as recited in claim 16, wherein the resistive memory elements have an on-state resistance R_{ON} of at least about 10 ohms.

28. The method as recited in claim 16, wherein the row select switch devices and the column select switching devices are transistors.

29. The method as recited in claim 28, wherein the resistive memory elements have an on-state resistance R_{ON} of at least about 100 ohms.

30. The method as recited in claim 16, wherein the resistive memory elements are memristors.
